(19) United States
(12) Patent Application Publication
(10) Pub. No.: US 2014/0333179 A1
(43) Pub. Date: Nov. 13, 2014

(54) VIBRATION GENERATING APPARATUS

(71) Applicants: SAMSUNG ELECTRO-MECHANICS CO., LTD., Suwon-Si (KR); IUCF-HYU (Industry-University Cooperation Foundation Hanyang University), Seoul (KR)

(72) Inventors: Hwa Young Oh, Suwon-Si (KR); Seung Hyeon Jeong, Suwon-Si (KR); Gun Hee Jang, Seoul (KR); Ja Hyun Nam, Seoul (KR); Tae Heum Yeon, Seoul (KR); Young Jin Kim, Seoul (KR)

(73) Assignees: SAMSUNG ELECTRO-MECHANICS CO., LTD., Suwon-Si (KR); IUCF-HYU (Industry-University Cooperation Foundation Hanyang University), Seoul (KR)

(21) Appl. No.: 14/275,743

(22) Filed: May 12, 2014

(30) Foreign Application Priority Data
May 13, 2013 (KR) 10-2013-0054043
Nov. 29, 2013 (KR) 10-2013-0146897

(51) Int. Cl. H01L 41/09

(52) U.S. Cl. CPC H01L 41/09
USPC 310/323.01

(57) ABSTRACT

There is provided a vibration generating apparatus including: a piezoelectric element fixedly attached to a vibration transfer member and expanded and contracted in a direction from an inner surface thereof toward an outer surface thereof or in a direction from the outer surface thereof toward the inner surface thereof when power is applied thereto; and a vibration element connected to the piezoelectric element to vibrate.

### CROSS-REFERENCE TO RELATED APPLICATIONS

This application claims the benefit of Korean Patent Application Nos. 10-2013-0054043 filed on May 13, 2013 and 10-2013-0146897 filed on Nov. 29, 2013, with the Korean Intellectual Property Office, the disclosures of which are incorporated herein by reference.

### BACKGROUND

The present disclosure relates to a vibration generating apparatus.

A vibration generating apparatus, such as a component or system capable of converting electrical energy into mechanical vibrations using, for example, the principle of the generation of electromagnetic force, can be mounted in a mobile phone, or the like, and can thereby be used for purposes such as silently notifying a user of call reception by transferring vibrations thereto. In addition, in accordance with the rapid growth in the market for mobile devices such as mobile phones, and the like, and the trend for added functionality in mobile devices, mobile phone components having a small size and high quality have been desired. Accordingly, the need for a vibration generating apparatus having a novel structure capable of overcoming disadvantages of existing vibration generating apparatuses and having improved quality has also increased.

Further, as touchscreens have been adopted into devices such as mobile phones, including smartphones, it is desirable to adopt vibration generating apparatuses to generate vibrations at the time of touching the touchscreen of these devices.

In one embodiment, vibrations generated for a touch interaction with a touchscreen can be as follows. First, as the frequency of vibrations generated at the time of such touch interactions with a touchscreen can be greater than that of vibrations generated at the time of call reception, an operational lifespan of a vibration generating apparatus needs to be increased. Second, in some embodiments, user satisfaction can be increased when a user experiences vibrations at the time of a touch interaction with a touchscreen and a response speed of the vibrations increases as a speed of touch interactions with a touchscreen increases.

As a product capable of implementing one or more of the characteristics as described above, there is provided a piezo haptic actuator. Such a piezo haptic actuator uses the principle of an inverse piezoelectric effect, in which displacement of a piezo element is generated when a voltage is applied thereto, and vibration element force is generated by allowing a mass body to move due to the generated displacement.

In some embodiments, a vibration element having such a structure may have sufficiently stable vibration characteristics since a frequency bandwidth over which a predetermined minimum level of vibration element force can be achieved is relatively wide. In some embodiments, a vibration element may provide vibrations having a range of frequencies within a predetermined frequency range, rather than a single frequency. In some embodiments, the piezo haptic actuator may provide rapid operational response characteristics, and can be used for implementing haptic vibrations in mobile devices such as mobile phones, and the like.

However, in some embodiments, such as where displacement and vibration characteristics maybe achieved with a piezo element that is elongated, a length of the piezo haptic actuator may be increased and the vulnerability of the piezo haptic actuator to drop impacts may be increased.

That is, in some implementations, a plate having a spring action can be fixedly attached to a vibration transfer member composed of an upper case having a rectangular parallelepiped shape and a bracket. Here, a length of the plate can correspond to a length of the vibration transfer member.

The piezo hepatic actuator can have a structure in which when power is applied to the piezo element in a state in which the piezo element is fixedly attached to the plate, the plate is vertically displaced, together with the piezo element, and the mass body connected to a central portion of the plate moves vertically to thereby generate vibrations.

Therefore, sufficient displacement and vibrations maybe achieved when the piezo element is relatively long, and such an elongated piezo element may be easily damaged when subjected to a drop impact.

### RELATED ART DOCUMENT

(Patent Document 1) Korean Patent Laid-Open Publication No. 2006-0000894

### SUMMARY

An aspect of the present disclosure may provide a vibration generating apparatus able to be miniaturized and having a reduced volume.

According to an aspect of the present disclosure, a vibration generating apparatus may include: a piezoelectric element fixedly attached to a vibration transfer member and expanded and contracted in a direction from an inner surface thereof toward an outer surface thereof or in a direction from the outer surface thereof toward the inner surface thereof when power is applied thereto; and a vibration element connected to the piezoelectric element to vibrate.

The piezoelectric element may have a cylindrical shape.

A longitudinal cross-section of the piezoelectric element may have a polygonal shape.

The vibration element may include an elastic member attached to one surface of the piezoelectric element to be vibrated.

The vibration element may further include a mass body fixedly attached to the elastic member to be vibrated together with the elastic member.

The elastic member may include: a plurality of coupling parts bonded to one surface of the piezoelectric element; a plurality of extension parts extended from the plurality of coupling parts in the direction from the outer surface of the piezoelectric element toward the inner surface thereof, respectively; and a mass body mounting part connected to the plurality of extension parts and providing a region on which the mass body is mounted.

The elastic member may include a plurality of coupling parts having one end bonded to one surface of the piezoelectric element, and a mass body mounting part connected to one or more other ends of the plurality of coupling parts and providing a region on which the mass body is mounted.

The mass body may be bonded to at least one of upper and lower surfaces of the mass body mounting part.

The vibration transfer member may include an installation part to which the piezoelectric element is fixedly attached.

The vibration transfer member may be composed of an upper case having an internal space and a bracket coupled to a lower edge portion of the upper case and including the installation part.

The installation part may have a cylindrical shape, and the piezoelectric element may include a plurality of piezoelectric elements portions disposed to be spaced apart regularly or irregularly from each other in a circumferential direction and attached to the installation part.

The installation part may include a protruding catch disposed between the plurality of piezoelectric elements.

According to another aspect of the present disclosure, a vibration generating apparatus may include: a vibration transfer member including an installation part; a piezoelectric element fixedly attached to the installation part and expanded and contracted in a direction from an inner surface thereof toward an outer surface thereof or in a direction from the outer surface thereof toward the inner surface thereof when power is applied thereto; an elastic member connected to the piezoelectric element to be vibrated; and a mass body attached to the elastic member to be vibrated together with the elastic member.

The piezoelectric element and the installation part may have a cylindrical shape, and the piezoelectric element may be fixedly attached to an inner surface or an outer surface of the installation part.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a view schematically illustrating the configuration of a vibration generating apparatus according to an exemplary embodiment of the present disclosure;

FIG. 2 is a perspective view illustrating a piezoelectric element and an elastic member provided in the vibration generating apparatus according to an exemplary embodiment of the present disclosure;

FIGS. 3 and 4 are views illustrating an operation of the vibration generating apparatus according to an exemplary embodiment of the present disclosure;

FIG. 5 is a partially exploded perspective view illustrating a vibration generating apparatus according to another exemplary embodiment of the present disclosure;

FIG. 6 is a partially exploded perspective view illustrating a vibration generating apparatus according to another exemplary embodiment of the present disclosure; and

FIG. 7 is a view illustrating a modified example of an elastic member provided in a vibration generating apparatus.

### DETAILED DESCRIPTION

Hereinafter, embodiments of the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

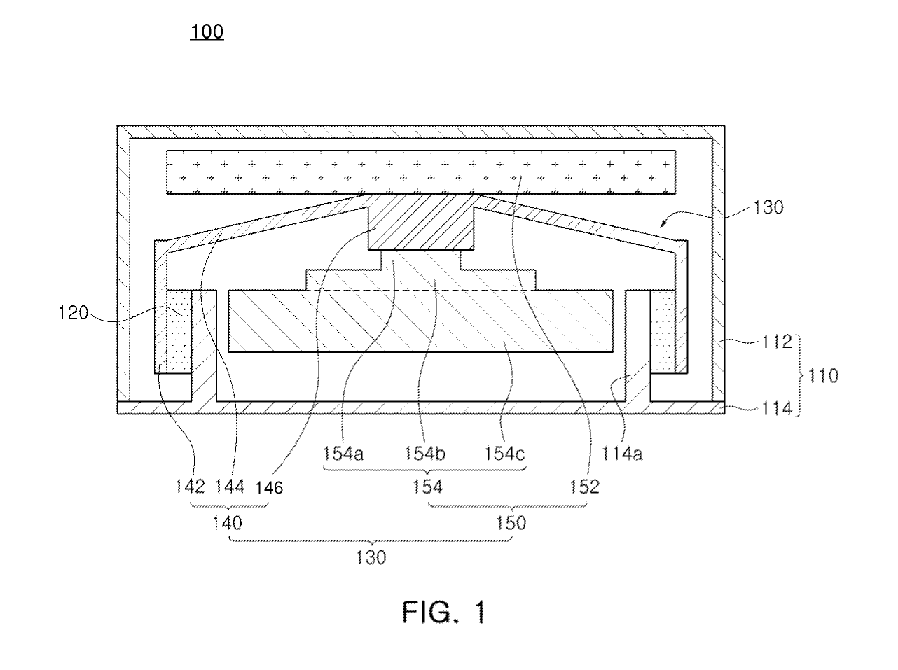

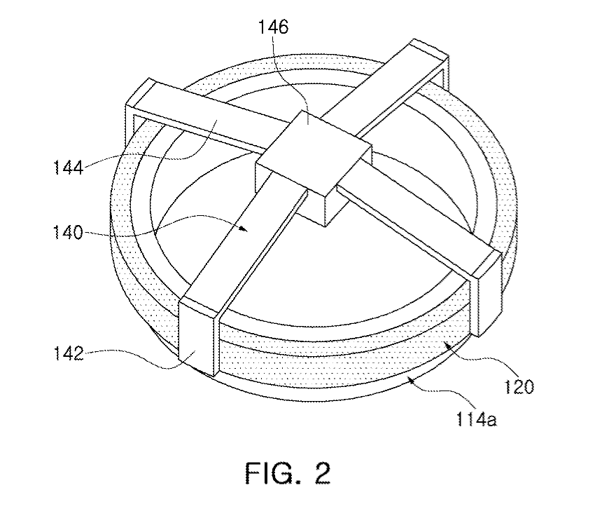

FIG. 1 is a view schematically illustrating the configuration of a vibration generating apparatus according to an exemplary embodiment of the present disclosure, and FIG. 2 is a perspective view illustrating a piezoelectric element and an elastic member provided in the vibration generating apparatus according to the exemplary embodiment of the present disclosure.

Referring to FIGS. 1 and 2, a vibration generating apparatus 100 according to this exemplary embodiment of the present disclosure may include a vibration transfer member 110, a piezoelectric element 120, and a vibration element 130 by way of example.

The vibration transfer member 110 may form an exterior surface of the vibration generating apparatus 100 and include, for example, an upper case 112 and a bracket 114.

The upper case 112 can form a container, such as a circular container, having a lower portion that can be open. In addition, the bracket 114 may be coupled to a lower edge portion of the opened upper case 112 to form a closed space together with the upper case 112.

Meanwhile, an installation part 114a for coupling with the piezoelectric element 120 may be provided on the bracket 114. As an example, the installation part 114a may have a cylindrical shape, and the piezoelectric element 120 may be fixedly attached to an outer peripheral surface of the installation part 114a.

However, a shape of the installation part 114a is not limited thereto, and the installation part 114a may have a shape corresponding to that of the piezoelectric element 120. For example, the installation part 114a may have a cylindrical shape or a square pillar shape.

In addition, the installation part 114a may be formed of a single protrusion or a plurality of protrusions disposed around a portion of the bracket 114. In some embodiments, a series of protrusions can be spaced apart from each other, regularly or irregularly, in a pattern or in a circumferential direction, and formed such that an imaginary line connecting the protrusions of the installation part 114a forms or approximates a circle or another shape.

Meanwhile, although the case in which the installation part 114a is formed integrally with the bracket 114 is described by way of example in the present exemplary embodiment, the installation part 114a is not limited thereto, and may be manufactured separately from the bracket and attached to the bracket 114.

In addition, although the case in which the installation part 114a is integrated with the bracket 114 is described by way of example in the present exemplary embodiment, the installation part 114a may be provided with the upper case 112.

The piezoelectric element 120 may be fixedly attached to the vibration transfer member 110 and have a cylindrical shape. That is, the piezoelectric element 120 may be fixed to the installation part 114a of the bracket 114 and have, for example, a cylindrical shape (in which a longitudinal cross-section thereof has a circular ring shape).

In other words, an inner surface of the piezoelectric element 120 may be bonded to an outer surface of the installation part 114a of the bracket 114.

As described above, the inner surface of the piezoelectric element 120 and the outer surface of the installation part 114a of the bracket 114 may have shapes corresponding to each other.

Meanwhile, the piezoelectric element 120 may be polarized in a radial direction, such that when a voltage is applied thereto, the piezoelectric element may be expanded or contracted in the radial direction. In other words, the piezoelectric element 120 may be expanded and contracted in a direction from the inner surface thereof toward an outer surface thereof or in a direction from the outer surface thereof toward the inner surface thereof when power is applied thereto.

Here, terms with respect to directions are explained with reference to FIG. 1. The radial direction refers to a horizontal direction, such as a direction from an outer peripheral surface of the vibration transfer member 110 toward the piezoelectric element 120 or a direction from the piezoelectric element 120 toward the outer peripheral surface of the vibration transfer member 110. A circumferential direction refers to a rotational direction, such as along the outer peripheral surface of the vibration transfer member 110 or the piezoelectric element 120 and may or may not be associated with an outer or circumferential surface.

In addition, a thickness direction refers to a vertical direction, such as a direction from the bracket 114 toward an upper surface of the upper case 112, or a direction from the upper surface of the upper case 112 toward the bracket 114 in FIG. 1.

Meanwhile, a circuit board (not shown) for supplying power may be connected to the piezoelectric element 120. In addition, the circuit board may be formed of a flexible circuit board so that the piezoelectric element 120 may be smoothly expanded and contracted.

The vibration element 130 may be connected to the piezoelectric element 120 to thereby vibrate. Meanwhile, the vibration element 130 may include an elastic member 140 and a mass body 150.

The elastic member 140 may be connected to the piezoelectric element 120 to generate vibrations at the time of deformation of the piezoelectric element 120. To this end, the elastic member 140 may include a coupling part 142 fixed to the outer surface of the piezoelectric element 120, an extension part 144 extending from the coupling part 142 in an inner radial direction, and a mass body mounting part 146 disposed pm the extension part 144 distal to the coupling part 142 with the mass body 150 mounted thereto.

The coupling part 142 may be fixedly attached to the outer surface (that is, the outer peripheral surface) of the piezoelectric element 120. Meanwhile, in one embodiment, four coupling parts 142 may be provided to be disposed in four positions of the outer surface of the piezoelectric element 120 so that they are spaced apart from each other in the circumferential direction.

However, the present disclosure is not limited thereto, but the number of coupling parts 142 may be changed so that the coupling parts 142 may be attached to two, three, or five or more positions on the outer surface of the piezoelectric element 120.

In addition, a length of the coupling part 142 may be longer than a thickness of the piezoelectric element 120. In other words, an upper end portion of the coupling part 142 may protrude upwardly from the piezoelectric element 120.

Meanwhile, the extension part 144 may be extended from the coupling part 142, and an angle between the extension part 144 and an upper surface of the piezoelectric element 120 in some embodiments may be approximately 45 degrees.

In addition, the number of extension parts 144 may correspond to the number of coupling part 142. In the present exemplary embodiment, four extension parts 144 corresponding to the four coupling parts 142 may be provided.

Meanwhile, the mass body mounting part 146 may be connected to the other end of the extension part 144 and have flat upper and/or lower surfaces on which the mass body 150 is disposed.

The mass body 150 may be fixedly attached to the elastic member 140 to serve to amplify an amount of vibrations.

Meanwhile, the mass body 150 may include first and second mass bodies 152 and 154.

The first mass body 152 may be fixed to the upper surface of the mass body mounting part 146 and can in some embodiments comprise a flattened or coin shape.

In addition, the second mass body 154 may include a portion or a series of portions comprising a flattened or coin shape. In one embodiment a first coin portion 154a can be fixed to the lower surface of the mass body mounting part 146, a second coin portion 154b having a diameter larger than that of the first coin portion 154a, and a third coin portion 154c having a diameter larger than that of the second coin portion 154b.

However, although the case in which the mass body 150 includes the first and second mass bodies 152 and 154 is described by way of example in the present exemplary embodiment, the mass body is not limited thereto. In some embodiments, the mass body 150 may comprise only one of the first and second mass bodies 152 and 154 or comprise both the first and second mass bodies 152 and 154.

That is, only the first mass body 152 may be mounted on the mass body mounting part 146, only the second mass body 154 may be mounted on the mass body mounting part 146, or both of the first and second mass bodies 152 and 154 may be mounted on the mass body mounting part 146 as in the present exemplary embodiment.

In addition, while in some embodiments the second mass body 154 includes first to third coin portions 154a to 154c the second mass body can have other configurations. The configuration of the second mass body 154 in various embodiments may be varied so long as the second mass body 154 may be fixed to the lower surface of the mass body mounting part 146 and be disposed inwardly of the piezoelectric element 120.

Further, the first mass body 152 and/or its subparts may also have various cross-sectional shapes such as a square shape, a pentagonal shape, an octagonal shape, or the like, so as to increase mass.

Meanwhile, although not shown, an element for buffering such as a damping member, a magnetic fluid, or the like, may be provided to an inner surface of the vibration transfer member 110, the inner surface of the piezoelectric element 120, and/or the elastic member 140 so as to prevent the generation of noise and damages resulting from a contact therebetween.

As described above, in some embodiments the vibration generating apparatus 100 can be made to not have a rectangular parallelepiped shape, and in some embodiments an overall volume of the vibration generating apparatus 100 may be decreased. In some embodiments, the vibration generating apparatus 100 may have, for example, a circular coin shape, and the volume thereof may be decreased.

Further, since the mass body 150 in some embodiments may be composed of the first and second mass bodies 152 and 154, the mass bodies maybe disposed in empty spaces formed inside and above the piezoelectric element 120 having the cylindrical shape, whereby the mass of the mass body 150 may be increased to cause an increase in the intensity of vibrations.

Hereinafter, an operation of a vibration generating apparatus according to an exemplary embodiment of the present disclosure will be described with reference to the accompanying drawings.

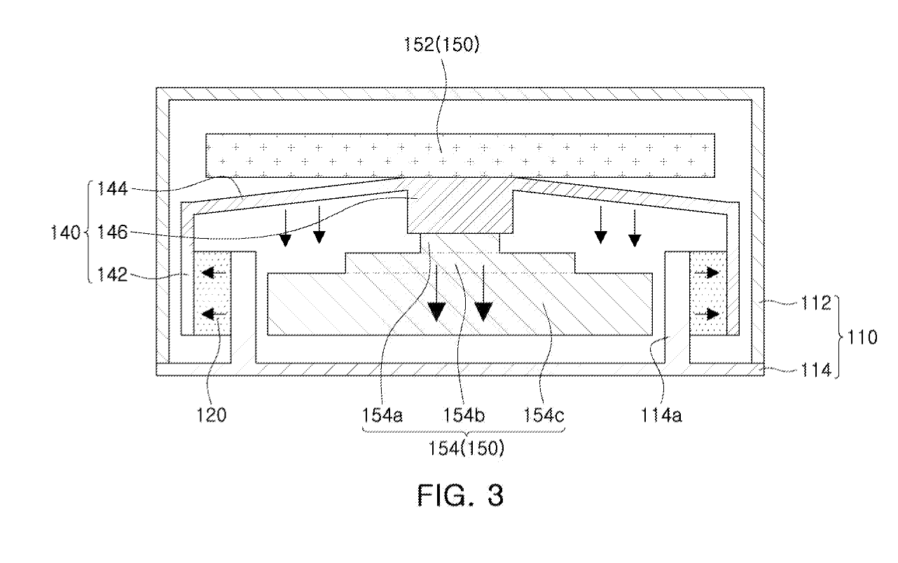

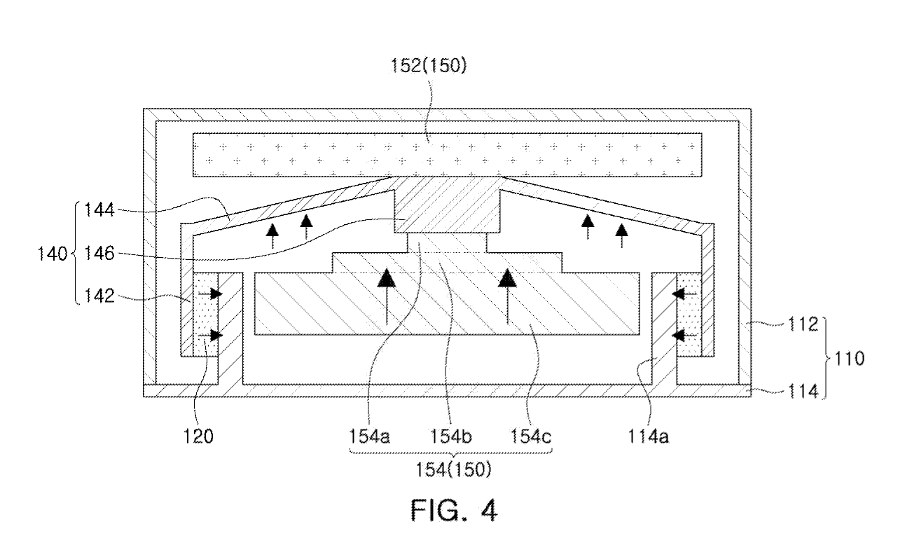

FIGS. 3 and 4 are views illustrating an operation of a vibration generating apparatus according to an exemplary embodiment of the present disclosure.

Referring to FIGS. 3 and 4, first, when a voltage is applied to inner and outer peripheral portions of the piezoelectric element 120 having the cylindrical shape (ring shape), the piezoelectric element may be expanded and contracted in the radial direction. Therefore, the coupling part 142 of the elastic member 140 fixed to the outer peripheral surface of the piezoelectric element 120 may move together with the piezoelectric element 120 in the radial direction.

Therefore, one end or a peripheral portion of the extension part 144 extended from the coupling part 142 may move together with the coupling part 142 in the radial direction, and another end or a central portion of the extension part 144 may move in the vertical direction.

As a result, the mass body mounting part 146 connected to the other end of the extension part 144 and the mass body 150 may also be vibrated together with the other end of the extension part 144 in the vertical direction, and since the mass body 150 is mounted on the mass body mounting part 146, the amount of vibrations may be increased.

Hereinafter, a vibration generating apparatus according to another exemplary embodiment of the present disclosure will be described with reference to the accompanying drawing. However, the same reference numerals will be used to designate the same elements as the above-mentioned elements.

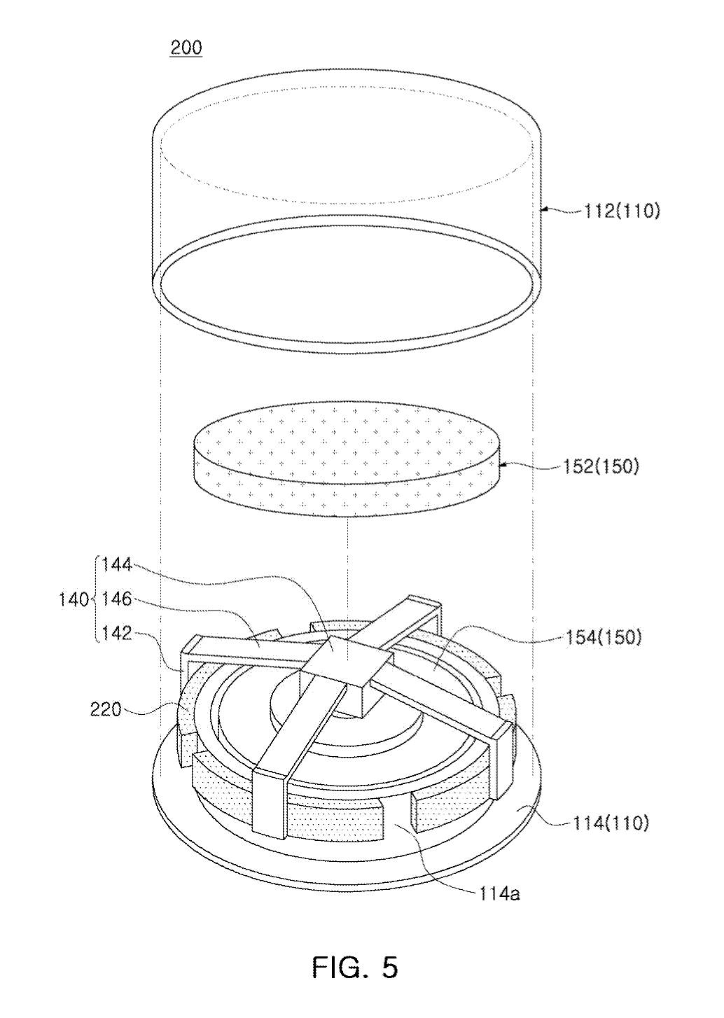

FIG. 5 is a partially exploded perspective view illustrating a vibration generating apparatus according to another exemplary embodiment of the present disclosure.

Referring to FIG. 5, a vibration generating apparatus 200 according to this exemplary embodiment of the present disclosure may include, for example, a vibration transfer member 110, a piezoelectric element 220, and a vibration element 130 including an elastic member 140 and a mass body 150.

Meanwhile, since the vibration transfer member 110 and the vibration element 130 including the elastic member 140 and the mass body 150 provided in the vibration generating apparatus 200 according to this exemplary embodiment of the present disclosure have configurations substantially similar to those described in the previous exemplary embodiment, a detailed description thereof will be omitted.

The piezoelectric element 220 may be attached to an installation part 114a having a cylindrical shape, and a plurality of piezoelectric elements portions may be disposed to be spaced apart from each other regularly or irregularly. That is, an inner peripheral surface of the piezoelectric element 220 maybe bonded or otherwise attached to an outer peripheral surface of the installation part 114a.

Meanwhile, although the installation part 114a can have a cylindrical shape in some embodiments, the installation part 114a is not limited thereto. The shape and number of installation parts 114a may vary in different embodiments and can correspond to the number of piezoelectric elements 220, or there can be more installation parts 114a or less installation parts 114a than the number of piezoelectric elements 220. In some embodiments, the pattern defined by the installation parts 114a, such as by an imaginary line connecting the installation parts 114a, may form, or approximate, a circle or another shape.

In other words, in the case in which four piezoelectric elements 220 are provided, four installation parts 114a may protrude from the bracket 114. In this case, the imaginary line connecting the installation parts 114a may form or approximate a circle or another shape.

In addition, the piezoelectric element 220 may be polarized in a radial direction, such that when a voltage is applied thereto, the piezoelectric element 220 may be expanded or contracted in the radial direction.

The plurality of piezoelectric elements 220 may be disposed in a pattern spaced apart from each other in a circumferential direction as described above. In some embodiments, the piezoelectric elements 220 may be more easily deformed as compared to a piezoelectric element having an uninterrupted cylindrical shape. In some embodiments, a plurality of piezoelectric elements 220 can be disposed in a pattern spaced apart from each other regularly or irregularly in a circumferential direction, rigidity of the piezoelectric elements 220 maybe decreased, and the piezoelectric elements 220 may be more easily deformed.

In some embodiments, the piezoelectric elements 220 may have greater driving efficiency, such as where the piezoelectric elements 220 may be more easily deformed.

Hereinafter, a vibration generating apparatus according to another exemplary embodiment of the present disclosure will be described with reference to the accompanying drawing. Meanwhile, in the present exemplary embodiment, the same reference numerals will be used to designate the same elements throughout the accompanying drawing. In addition, detailed descriptions of elements the same as those of the above-mentioned elements will be omitted.

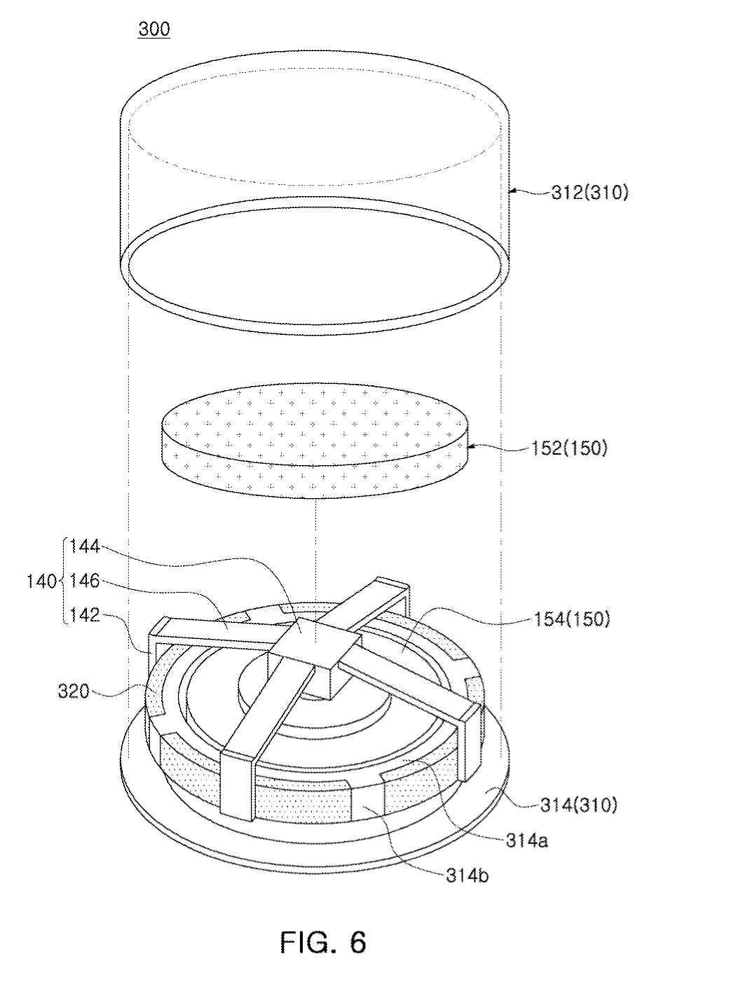

FIG. 6 is a partially exploded perspective view illustrating a vibration generating apparatus according to another exemplary embodiment of the present disclosure.

Referring to FIG. 6, a vibration generating apparatus 300 according to this exemplary embodiment of the present disclosure may include, for example, a vibration transfer member 310, a piezoelectric element 320, and a vibration element 130 including an elastic member 140 and a mass body 150.

The vibration transfer member 310 may form an exterior appearance of the vibration generating apparatus 300 and include, for example, an upper case 312 and a bracket 314.

The upper case 312 may have a circular container of which a lower portion is opened. In addition, the bracket 314 may be coupled to a lower edge portion of the opened upper case 312 to form a closed space together with the upper case 312.

Meanwhile, an installation part 314a for coupling with the piezoelectric element 320 may be provided in the bracket 314. As an example, the installation part 314a may have an approximately cylindrical shape, and the piezoelectric element 320 may be fixed to an outer peripheral surface of the installation part 314a.

Meanwhile, extensions 314b may be provided with the installation part 314a in order to support both side surfaces of the piezoelectric element 320. That is, the extensions 314b may protrude from the outer peripheral surface of the installation part 314a to be disposed between the plurality of piezoelectric elements 320.

However, although the case in which the installation part 314a is formed integrally with the bracket 314 is described by way of example in the present exemplary embodiment, the installation part 314a is not limited thereto and may be manufactured separately from the bracket 314 and assembled to the bracket 314.

In addition, although the case in which the installation part 314a is integrated with the bracket 314 is described by way of example in the present exemplary embodiment, the installation part 314a may be provided with or anchored to the upper case 312.

The piezoelectric element 320 may be attached to the installation part 314a, and the plurality of piezoelectric elements may be disposed to be spaced apart regularly or irregularly from each other. That is, the piezoelectric element 320 may be attached to the installation part 314a so that an inner peripheral surface thereof is bonded to the outer peripheral surface of the installation part 314a and both side surfaces of the piezoelectric element 320 are supported by the protruding catches 314b of the installation part 314a.

Meanwhile, both side surfaces of the piezoelectric element 320 simply contact the protruding catches 314b but are not bonded thereto.

In addition, the piezoelectric element 320 may be polarized in a radial direction, such that when a voltage is applied thereto, the piezoelectric element may be expanded or contracted in the radial direction.

The plurality of piezoelectric elements 320 may be disposed in a pattern spaced apart from each other in a circumferential direction as described above. In some embodiments, the piezoelectric elements 320 may be more easily deformed. That is, as compared to a piezoelectric element having an uninterrupted cylindrical shape. In some embodiments, a plurality of piezoelectric elements 320 can be disposed in a pattern spaced apart from each other in a circumferential direction, rigidity of the piezoelectric elements 320 may be decreased, and the piezoelectric elements 320 maybe more easily deformed.

In some embodiments, the piezoelectric elements 320 may have greater driving efficiency, such as where the piezoelectric elements 320 may be more easily deformed.

Further, in some embodiment one or both side surfaces of the piezoelectric element 320 maybe supported by the extensions 314b, such that the piezoelectric elements 320 maybe more easily deformed in the radial direction and in some embodiments the driving efficiency can be improved.

Meanwhile, since the elastic member 140 and the mass body 150 provided in the vibration generating apparatus 300 according to this exemplary embodiment of the present disclosure have configurations substantially similar to those described in the previous exemplary embodiment, a detailed description thereof will be omitted.

Hereinafter, a vibration generating apparatus according to another exemplary embodiment of the present disclosure will be described with reference to the accompanying drawing.

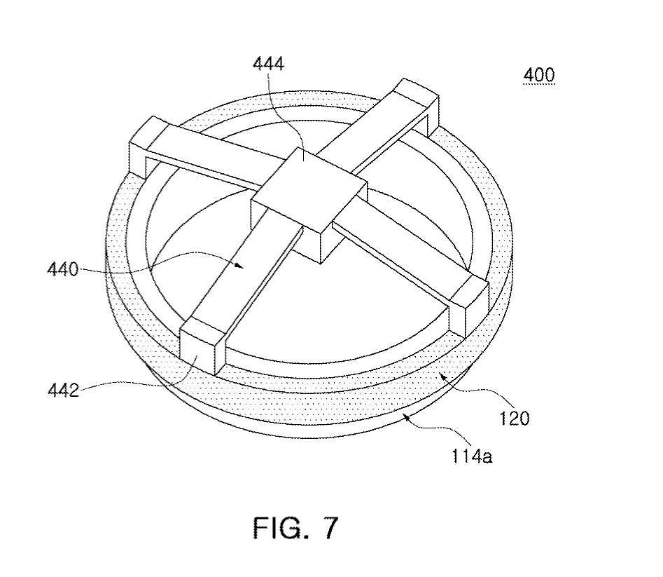

FIG. 7 is a view illustrating a modified example of an elastic member provided in a vibration generating apparatus.

Referring to FIG. 7, a vibration generating apparatus 400 according to this exemplary embodiment of the present disclosure may include, for example, a vibration transfer member 110, a piezoelectric element 120, and a vibration element including an elastic member 440 and a mass body 150.

Meanwhile, since the vibration transfer member 110, the piezoelectric element 120, and the mass body 150 provided in the vibration generating apparatus 400 according to this exemplary embodiment of the present disclosure have configurations substantially similar to those of the above-mentioned vibration generating apparatus 100 according to the previous exemplary embodiment of the present disclosure, a detailed description thereof will be omitted.

The elastic member 440 maybe attached to one surface of the piezoelectric element 120 to be vibrated. As an example, the elastic member 440 may include a plurality of coupling parts 442 having one ends bonded onto one surface of the piezoelectric element 120 and a mass body mounting part 444 connected to the other ends of the plurality of coupling parts and providing an installation region on which the mass body 150 is mounted.

For example, one ends of the coupling parts 442 may be bonded to an upper surface of the piezoelectric element 120, and the other ends of the coupling parts 442 may be connected to the mass body mounting part 444. In addition, the mass body mounting part 444 may be connected to the other ends of the plurality of coupling parts 442 and provide the installation region so that the mass body 150 may be disposed thereon.

As set forth above, according to exemplary embodiments of the present disclosure, since the overall volume of the vibration generating apparatus may be decreased through the use of the piezoelectric element having the above configuration, the vibration generating apparatus may be miniaturized.

While exemplary embodiments have been shown and described above, it will be apparent to those skilled in the art that modifications and variations could be made without departing from the spirit and scope of the present disclosure as defined by the appended claims.

What is claimed is:

1. A vibration generating apparatus, comprising:
a piezoelectric element fixedly attached to a vibration transfer member and expanded and contracted in a direction from an inner surface thereof toward an outer surface thereof or in a direction from the outer surface thereof toward the inner surface thereof when power is applied thereto; and
a vibration element connected to the piezoelectric element to vibrate.

2. The vibration generating apparatus of claim 1, wherein the piezoelectric element has a cylindrical shape.

3. The vibration generating apparatus of claim 1, wherein a longitudinal cross-section of the piezoelectric element has a polygonal shape.

4. The vibration generating apparatus of claim 1, wherein the vibration element includes an elastic member attached to one surface of the piezoelectric element to be vibrated.

5. The vibration generating apparatus of claim 4, wherein the vibration element further includes a mass body fixedly attached to the elastic member to be vibrated together with the elastic member.

6. The vibration generating apparatus of claim 5, wherein the elastic member includes:
a plurality of coupling parts bonded to one surface of the piezoelectric element;
a plurality of extension parts extended from the plurality of coupling parts in the direction from the outer surface of the piezoelectric element toward the inner surface thereof, respectively; and
a mass body mounting part connected to the plurality of extension parts and providing a region on which the mass body is mounted.

7. The vibration generating apparatus of claim 5, wherein the elastic member includes:
a plurality of coupling parts having one ends bonded to one surface of the piezoelectric element; and
a mass body mounting part connected to the other ends of the plurality of coupling parts and providing a region on which the mass body is mounted.

8. The vibration generating apparatus of claim 6, wherein the mass body is bonded to at least one of upper and lower surfaces of the mass body mounting part.

9. The vibration generating apparatus of claim 1, wherein the vibration transfer member includes an installation part to which the piezoelectric element is fixedly attached.

10. The vibration generating apparatus of claim 9, wherein the vibration transfer member is composed of an upper case having an internal space and a bracket coupled to a lower edge portion of the upper case and including the installation part.

11. The vibration generating apparatus of claim 9, wherein the installation part has a cylindrical shape, and
the piezoelectric element comprises a plurality of piezoelectric elements portions disposed to be spaced apart from each other in a circumferential direction and attached to the installation part.

12. The vibration generating apparatus of claim 11, wherein the installation part includes a protruding catch disposed between the plurality of piezoelectric elements.

13. A vibration generating apparatus, comprising:
a vibration transfer member including an installation part;
a piezoelectric element fixedly attached to the installation part and expanded and contracted in a direction from an inner surface thereof toward an outer surface thereof or in a direction from the outer surface thereof toward the inner surface thereof when power is applied thereto;
an elastic member connected to the piezoelectric element to be vibrated; and
a mass body attached to the elastic member to be vibrated together with the elastic member.

14. The vibration generating apparatus of claim 13, wherein the piezoelectric element and the installation part have a cylindrical shape, and
the piezoelectric element is fixedly attached to an inner surface or an outer surface of the installation part.

15. The vibration generating apparatus of claim 13, wherein the elastic member includes:
a plurality of coupling parts fixedly attached to the inner surface or the outer surface of the piezoelectric element;
a plurality of extension parts extended from the plurality of coupling parts in the direction from the outer surface of the piezoelectric element toward the inner surface thereof, respectively; and
a mass body mounting part connected to the plurality of extension parts and providing a region on which the mass body is mounted.

16. The vibration generating apparatus of claim 13, wherein the elastic member includes:
a plurality of coupling parts having one ends bonded to one surface of the piezoelectric element; and
a mass body mounting part connected to the other ends of the plurality of coupling parts and providing a region on which the mass body is mounted.

17. The vibration generating apparatus of claim 16, wherein one ends of the plurality of coupling parts are bonded to an upper surface of the piezoelectric element.

18. The vibration generating apparatus of claim 15, wherein the mass body is attached to at least one of upper and lower surfaces of the mass body mounting part.

19. The vibration generating apparatus of claim 14, wherein the piezoelectric element comprises a plurality of piezoelectric elements portions disposed to be spaced apart from each other in a circumferential direction and attached to the installation part.

20. The vibration generating apparatus of claim 19, wherein the installation part includes an extension disposed between the plurality of piezoelectric elements.

21. The vibration generating apparatus of claim 5, wherein the piezoelectric element is configured to vibrate in a direction of a first axis, and the mass element is configured to vibrate in a direction of a second axis, wherein the first axis is non-parallel to the second axis.

22. The vibration generating apparatus of claim 21, wherein the first axis is substantially orthogonal to the second axis.
